(19) United States
(12) Patent Application Publication
(10) Pub. No.: US 2002/0063558 A1
(43) Pub. Date: May 30, 2002

(54) Test head connection unit

(76) Inventors: Hideki Takeuchi, Tokyo (JP); Kazumi Okamoto, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/995,229

(22) Filed: Nov. 27, 2001

(30) Foreign Application Priority Data
Nov. 28, 2000 (JP) 2000-361609

(51) Int. Cl. G01R 1/00; G01R 31/02

(52) U.S. Cl. 324/158.1; 324/758

(57) ABSTRACT

Inconvenience that an auto-handler is not normally operated which is caused when an operator forgets the fixation between a test head and the auto-handler is solved. Sensors detect whether a measuring box is in a given connection height or not and also in a connection completion position relative to the auto-handler or not and decision result output means outputs the result of decision, so that the fixation between the test head and the auto-handler can be confirmed.

### BACKGROUND OF THE INVENTION

1. Field of the Invention

The invention relates to a test head connection unit capable of confirming whether an auto-handler for sorting ICs and a test head provided with an IC socket for measurement and the like are connected to each other or not when the auto-handler and the test head are connected to each other.

2. Related Art

A conventional test head connection unit is described with reference to FIGS. 3 to 5. FIG. 3(A) is a view showing a state before ICs are connected to a measuring box 3, and FIG. 3(B) is a view showing a state where the ICs are connected to the measuring box 3. FIG. 4(A) is a view showing a state before an auto-handler 1 and a test head 2 are connected to each other and FIG. 4(B) is a state where the auto-handler 1 and the test head 2 are connected to each other. FIG. 5(A) is a view showing a state before the auto-handler 1 and the measuring box 3 are connected to each other and FIG. 5(B) is a state where the auto-handler 1 and the measuring box 3 are connected to each other.

As shown in FIGS. 3 to 5, an IC test system for measuring or testing ICs is structured by the auto-handler 1 for sorting the ICs and the test head 2 provided with an IC socket for measurement and the like. As shown in FIG. 3, the auto-handler 1 is provided with a moving carrier 5 on which a plurality of carrier dowels 5A are arranged to be freely conveyed. ICs are transferred to the plurality of carrier dowels 5A in the moving carrier 5 by a loader section of the auto-handler 1, not shown. The moving carrier 5 circulates inside the auto-handler 1 and it is lowered by a lifter 7 provided in the measuring part, to a measuring box 3, described later, together with a contact pusher 6.

As shown in FIG. 4, the test head 2 is detachably provided relative to the auto-handler 1. The measuring box 3 is elastically supported on the test head 2 by way of fixed metal fittings 11 to be movable up and down as shown in FIGS. 3 to 5. Cams 12 which are reciprocated by air cylinders 13 are provided on the side surfaces of the auto-handler 1, wherein the measuring box 3 which was positioned at a given position is connected to the auto-handler 1 side by the connection between the rollers 10 and cams 12.

A plurality of IC sockets 8 are placed on the measuring box 3 and the plurality of guide pins 9 stand upright on the measuring box 3. A guide bush 5B is provided on the moving carrier 5 at the auto-handler 1 side while a guide bush 6A is provided on the contact pusher 6. When the moving carrier 5 and the contact pusher 6 are lowered toward the measuring box 3, the guide pins 9 and the guide bushes 5B and 6A are engaged with one another, thereby effecting positioning. Further, guide pins 8A stand upright on the IC sockets 8 of the measuring box 3, wherein when the carrier dowels 5A of the moving carrier 5 are retained by the guide pins 8A, both the IC sockets 8 and the carrier dowels SA are positioned.

As shown in FIG. 3, when the moving carrier 5 and the contact pusher 6 are lowered toward the measuring box 3 by the lifter 7, so that leads of ICs to be tested contact contacts of the IC socket 8 under pressure so that electric characteristics of the ICs to be tested are measured or tested. A measurement section 4 shown in FIG. 3 is structured as a temperature controlled bath so as to maintain a measuring environment at a constant temperature.

A connecting operation between the auto-handler 1 and the test head 2 is explained next. First, in a state as shown in FIG. 4(A), the test head 2 is moved toward and insert into the lower portion of the auto-handler 1 in the direction of the arrow shown in FIG. 4(A), so that the entire test head 2 provided with measuring box 3 is moved upward in the direction of the arrow as shown in FIG. 4(B) and 5(A).

Then the entire test head 2 is moved upward to reach a given connection height, which state has been visually confirmed by an operator, and the operator operates operating a manual air pressure switching valve, not shown, to drive the air cylinder 13 as shown in FIG. 5(B). As a result, the cams 12 move in the direction of the arrow in FIG. 5(B), so that the rollers 10 at the measuring box 3 side are driven and guided by the cams 12, thereby pressing the measuring box 3 toward the auto-handler 1 side. As a result, the connection between the auto-handler 1 and the test head 2 is completed.

According to the conventional test head connection unit, the connection state between the test head 2 and the auto-handler 1 is only visually confirmed by and operator. If an operator starts a normal operation when forgetting the proper connection between the auto-handler 1 and the test head 2, the moving carrier 5 and the contact pressure 6 are lowered toward the measuring box 3 side while the measuring box 3 comes off from a regular position so that a normal engagement between the moving carrier 5 and the measuring box 3 are not attained, arising circumstances under which a normal measurement can not be effected.

### SUMMARY OF THE INVENTION

In view of the foregoing circumstances, it is an object of the invention to provide a test head connection unit capable of confirming whether the auto-handler 1 and the test head 2 are properly connected to each other, thereby ensuring the reliable connection therebetween.

To achieve the above object, a test head connection unit according to a first aspect of the invention for detachably connecting an auto-handler (1) for sorting ICs to a test head (2) provided with means for measuring ICs (hereinafter referred to as measuring means (3) of the ICs) is characterized in comprising detection and decision means for detecting whether the measuring means (3) of the ICs is in a normal connection position or not relative to the auto-handler (1), and decision result output means for outputting result of decision from the detection and decision means.

The test head connection unit according to a second aspect of the invention is characterized in further comprising, in addition to the components set forth in the first aspect of the invention, moving means (13) for connecting between cams (12) and rollers (10) and moving either the cams (12) or rollers (10), wherein either the cams (12) or rollers (10) are disposed on the auto-handler (1) and the rest is disposed on the test head (2), wherein the detection and decision means comprising a position detection part for detecting a relative position between the cams (12) and the rollers (10) and a decision part for deciding whether the measuring means (3) of the ICs is in a normal connection position relative to the auto-handler (1) on the basis of the result of detection by the position detection part.

The test head connection unit according to a third aspect of the invention is characterized in that the auto-handler (1) in the first or second aspect of the invention moves the test head (2) to a normal connection position by allowing cams (12) to drive the rollers (10), and the detection decision means comprises a position detection part for detecting whether the test head (2) is disposed in the connection position and a position decision part for deciding whether the test head (2) is in the connection position on the basis of the result of decision of the position detection part.

Reference numerals in the brackets set fort above are provided for comparing with the drawings, but they do not limit the construction of the invention.

### BRIEF DESCRIPTION OF THE DRAWINGS

FIG. 1 is a sectional view showing a test head connection unit according to a preferred embodiment of the invention, wherein FIG. 1(A) shows a state before an auto-handler is connected to a measuring box, and FIG. 1(B) shows a state where the auto-handler is connected to the measuring box;

FIG. 2 is a view taken along the line C-C in FIG. 1(A);

FIG. 3 is a view showing a prior art test head connection unit, wherein FIG. 3(A) shows a state before ICs to be measured are connected to a measuring box, and FIG. 3(B) shows a state where the ICs to be measured are connected to the measuring box;

FIG. 4 is a view showing the prior art test head connection unit, wherein FIG. 4(A) shows a state before a test head is inserted into the autohandler, and FIG. 4(B) shows a state where the test head is inserted into the auto-handler; and

FIG. 5 is a sectional view showing the prior art test head connection unit, wherein FIG. 5(A) shows a state before the auto-handler is connected to the measuring box, and FIG. 5(B) shows a state where the auto-handler is connected to the measuring box.

### DETAILED DESCRIPTIONOF THE PREFERRED EMBODIMENTS

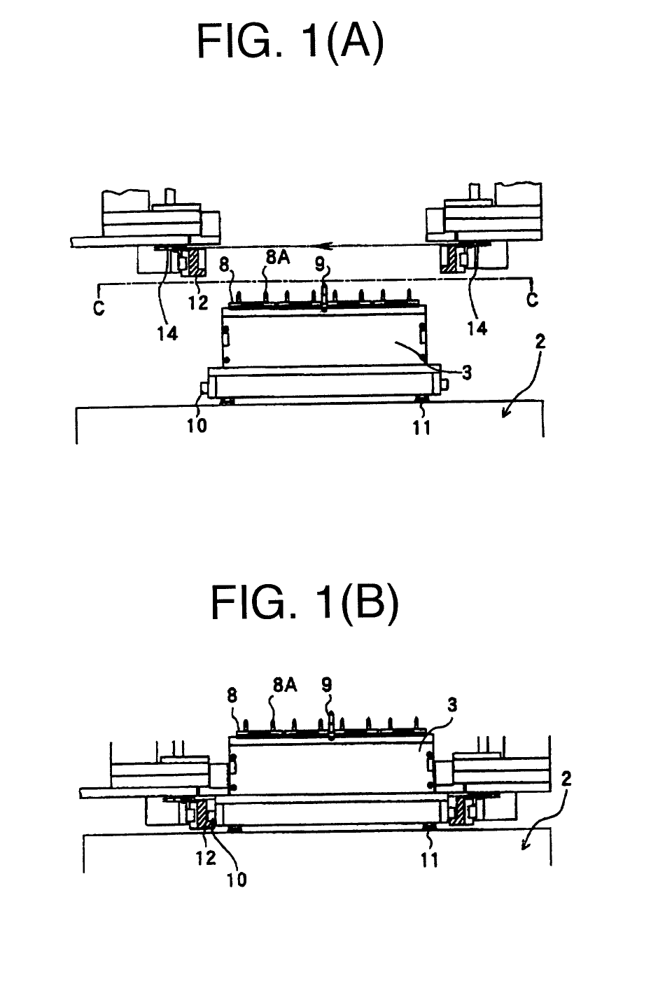

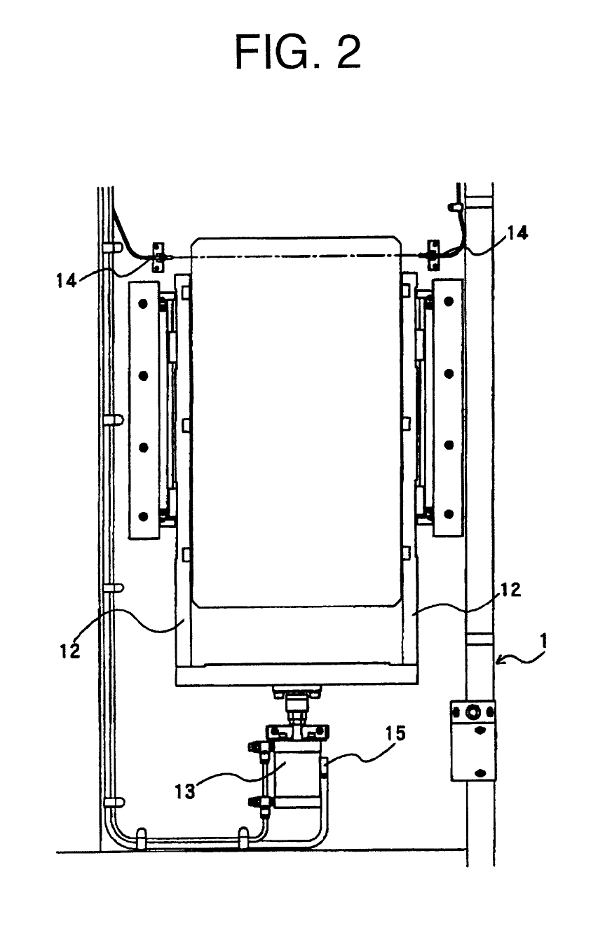

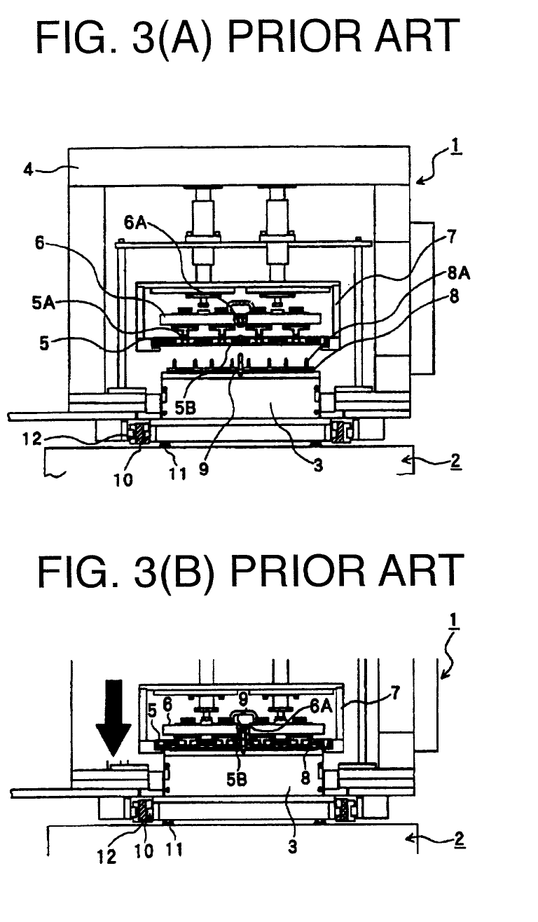

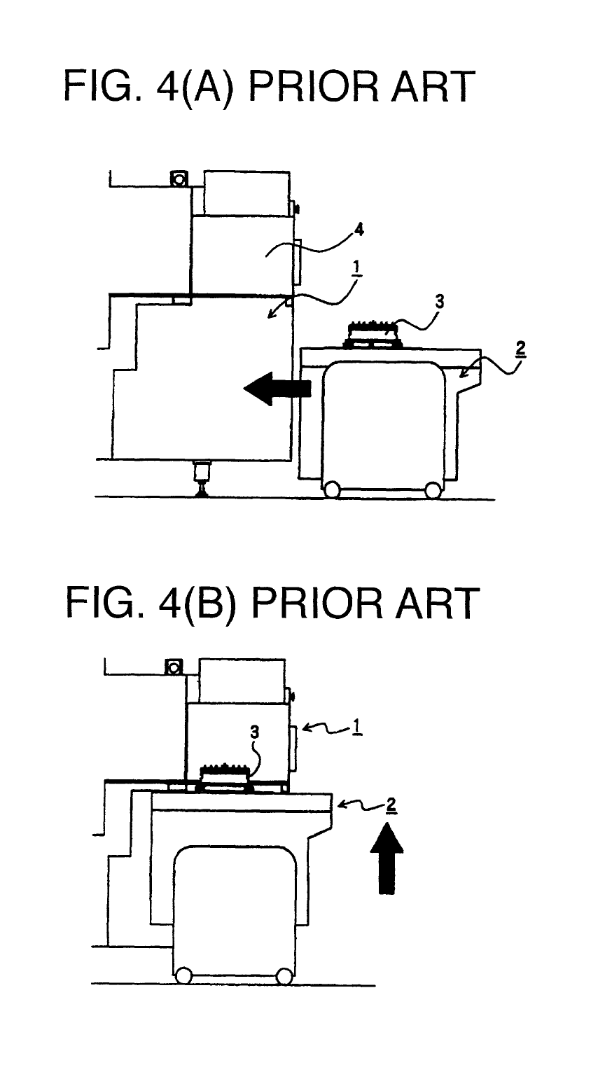

A test head connection unit according to a preferred embodiment of the invention is now described with reference to FIGS. 1 and 2. FIG. 1 is a sectional view showing a test head connection unit according to the preferred embodiment of the invention, wherein FIG. 1(A) shows a state before an auto-handler and a measuring box are connected to each other, and FIG. 1(B) is a view showing a state where the auto-handler and the measuring box are connected to each other. FIG. 2 is a view taken along the line C-C in FIG. 1(A). Components which are the same as those of the prior art as explained with reference to FIG. 3 to 5 are depicted by the same reference numerals and the explanation thereof is omitted.

According to the preferred embodiment, as shown in FIG. 1, a pair of optical sensors 14 are disposed on an auto-handler 1 while facing each other. The optical sensors 14 comprise a light emitting side at one side and a light receiving side at the other side. Each sensor 15 is disposed in each air cylinder 13 for driving each cam 12 so as to detect a position of each cam 12 which is driven as the piston operate when detecting a position of the piston inside the air cylinder 13. That is, the air cylinder 13 is an air cylinder provided with the sensor 15.

In the same manner as the prior art, it is confirmed in the following manner whether a measuring box 3 is in a connection height (set position) relative to the auto-handler 1 when an entire test head 2 is moved upward by inserting the test head 2 into the auto-handler 1.

In FIG. 1(A), in a state where the measuring box 3 does not reach a given connection height, which is caused, for example, when an operator forgot to move the test head 2 upward and the like, light from the optical sensor 14 at the light emitting side is not intercepted, and the optical sensors 14 at the light receiving side receives light. A test head neignt decision part, not shown, for receiving a detection signal (received light) from the optical sensorsl4 decides that the measuring box 3 is not in a connection height of the auto-handler 1 based on the detection signal (received light), and hence it decides that the test head 2 is not connected to the auto-handler 1, and allows an indication part, e.g., a display or a lamp, not shown, to indicate a non-connection state. Upon seeing the display, the operator moves the test head 2 upward or starts afresh to move the test head 2 upward.

In FIG. 1(B), in a state where the measuring box 3 and the auto-handler 1 are in a normal connection height, light from the optical sensor 14 at the light emitting side is intercepted, so that the optical sensor 14 at the light receiving side does not receive light. A test head height decision part, not shown, which receives detection signal (non-received light) from the optical sensor 14, decides that the measuring box 3 is in the same connection height as the auto-handler 1 based on the detection signal (non-received light), and allows an indication part, e.g., a display or lamp to indicate that the measuring box 3 is in a position of the same connection height as the auto-handler 1. The operator confirms that the measuring box 3 is in a proper connection height upon seeing the display, and proceeds to a next step.

Thereafter, when the cams 12 are driven by the air cylinder 13 in the same manner as the conventional method, the connection between the measuring box 3 and the auto-handler 1, namely, the connection between the test head 2 and the auto-handler 1 is effected. At this time, the position of the cams 12 is detected by a sensor 15 shown in FIG. 2.

For example, when the sensor 15 detects that the cams 12 are not in a given connection completion position (connection position) which is caused when an operator forgot to drive the air cylinder 13 and the like, a connection completion decision part, not shown, which receives a detection signal (other than the connection completion position) from the sensor 15, decides that the measuring box 3 is not connected to the auto-handler 1 based on the detection signal (other than the connection completion position), and allows an indication part, e.g., a display or a lamp, not shown, to display a non-connection state. Upon seeing the display, the operator drives the cams 12 by the air cylinder 13 upon seeing the display, thereby connecting the measuring box 3 to the auto-handler 1 or starts afresh the connection.

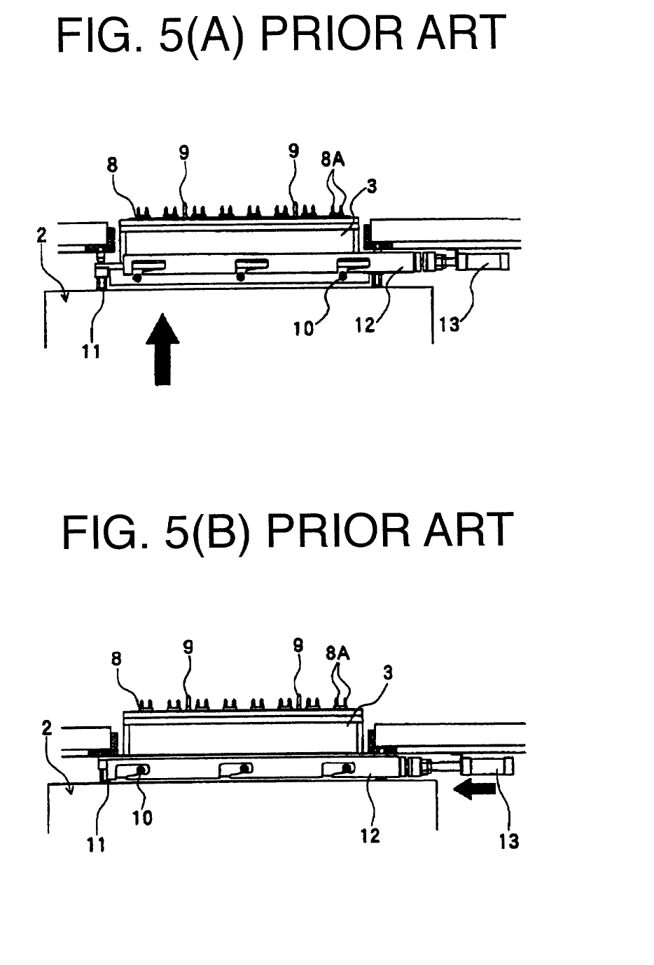

When the sensor 15 detected that the cams 12 are in a given connection completion position (see FIG. 5(B)), the connection completion decision part, not shown, upon completion of detection signal (connection completion position), decides that the measuring box 3 is properly connected to the auto-handler 1 on the basis of the detection signal (connection completion position), and allows an indication part, e.g., a display or a lamp, not shown, to display that the measuring box 3 and the auto-handler 1 are in a connection position. The operator confirms, upon seeing the display, that the measuring box 3 is properly connected to the auto-handler 1, and effects the lowering of the moving carrier 5 and the contact pusher 6 by a lifter 7 (see FIG. 3), then starts the measuring operation of the IC to be measured.

With the test head connection unit according to the preferred embodiment of the invention, the test head height decision part decides whether the measuring box 3 is in a normal connection height or not based on the detection by the optical sensor 14 and the connection completion decision part decides whether the cams 12 are moved to a connection completion position or not by the air cylinder 13 based on the detection by the position sensor 15, then the operator can confirm whether the test head 2 and the auto-handler 1 are properly connected to each other. The test head connection unit is safe and reliable because the operator starts the operation of the auto-handler 1 upon confirmation of the normal connection.

If the operator inputs an operation start instruction of the auto-handler 1 by an operation button, not shown, and the like in a state where the test head 2 and the auto-handler 1 are not connected to each other, it is preferable that the operation start instruction of the auto-handler 1 is cancelled and an alarm informing a non-operability is displayed by an appropriate fail safe mechanism, not shown, based on the result of decision from the test head height decision part and the connection completion decision part. As a result, the auto-handler 1 stops its operation.

Although the cams 12 are provided at the auto-handler 1 side and the rollers 10 are provided at the test head 2 side according to the preferred embodiment of the invention, they may be provided vice versa, i.e., the cams 12 are provided at the test head 2 side and the rollers 10 are provided at the auto-handler 1 side.

The optical sensor 14 as an example of a set position detection part for detecting whether the test head 2 is in a connection height (set position) or not is not limited to an optical sensor provided that if it can detect the position of heightof the measuring box 3 or test head 2. Further, the position sensor 15 as an example of a position detection part for detecting a relative position between the cams 12 and the rollers 10 may not be provided inside air cylinder 13 if it can detect the relative position between the cams 12 and the rollers 10.

As explained in detail above, according to the first aspect of the invention, it is possible to confirm that the auto-handler 1 and the test head 2 are connected in a normal state on the basis of the output of the result of decision, thereby ensuring the safe and reliable connection therebetween.

According to a second aspect of the invention, it is possible to confirm the fixation of the test head by the connection between the cams and rollers.

According to the third aspect of the invention, it is possible to confirm whether the test head is disposed at the connection position or not.

What is claimed is:

1. A test head connection unit for detachably connecting an auto-handler for sorting ICs to a test head provided with measuring means of the ICs comprising:
detection and decision means for detecting whether the measuring means of the ICs is in a normal connection position or not relative to the auto-handler; and
decision result output means for outputting a result of decision from the detection and decision means.

2. The test head connection unit according to claim 1 further comprising moving means for connecting between cams and rollers and moving either the cams or rollers, wherein either the cams or rollers are disposed on the auto-handler and the rest is disposed on the test head;
for detecting a relative position between the cams and the rollers and a decision part for deciding whether the measuring means of the ICs is in a normal connection position relative to the auto-handler on the basis of the result of detection bythe position detection part.

3. The test head connection unit according to claim 1 or 2, wherein the auto-handler moves the test head to a normal connection position by alloing the cams to drive the rollers, and said detection decision means comprises a position detection part for detecting whether the test head is disposed in the connection position and a position decision part for deciding whether the test head is in the connection position on the basis of the result of decision of the position detection part.
